(19) United States
(12) Patent Application Publication
(10) Pub. No.: US 2010/0147348 A1
(43) Pub. Date: Jun. 17, 2010

(54) Titania-Half Metal Composites As High-Temperature Thermoelectric Materials

(76) Inventor: Monika Backhaus-Ricoult, Horseheads, NY (US)

Correspondence Address: CORNING INCORPORATED, SP-TI-3-1, CORNING, NY, 14831, US

(21) Appl. No.: 12/333,670

(22) Filed: Dec. 12, 2008

(51) Int. Cl. H01L 35/34; H01L 35/12

(52) U.S. Cl. 136/201; 136/236.1

(57) ABSTRACT

A multiphase thermoelectric material includes a titania-based semiconducting phase and a half-metal conducting phase. The multiphase thermoelectric material is advantageously a nanocomposite material wherein the constituent phases are uniformly distributed and have crystallite sizes ranging from about 10 nm to 800 nm. The titania-based semiconducting phase can be a mixture of sub-stoichiometric phases of titanium oxide that has been partially reduced by the half-metal conducting phase. Methods of forming a multiphase thermoelectric material are also disclosed.

### BACKGROUND AND SUMMARY

The present invention relates to high temperature thermoelectric materials that can be used in thermoelectric devices for electric power generation.

The thermoelectric effect involves the conversion of thermal energy into electrical energy. Notably, a thermoelectric device such as a thermoelectric power generator can be used to produce electrical energy from a gradient in temperature, and advantageously can operate using waste heat such as industrial waste heat generated in chemical reactors, incineration plants, iron and steel melting furnaces, and in automotive exhaust. Efficient thermoelectric devices can recover about 20% or more of the heat energy released by such industrial systems, though due to the “green nature” of the energy, lower efficiencies are also of interest. Compared to other power generators, thermoelectric power generators operate without toxic gas emission, and with longer lifetimes and lower operating and maintenance costs

The conversion of thermal energy into electrical energy is based on the Seebeck effect, whereby, given two junctions between different materials at different temperatures, an electrical potential will develop that is proportional to both the temperature difference and the difference in the Seebeck coefficients between the two materials.

The Seebeck coefficient, also referred to as the thermopower or thermoelectric power of a material, is a measure of the magnitude of an induced thermoelectric voltage in response to a temperature difference across that material. The Seebeck coefficient, α, is defined as the thermoelectric voltage that develops across a material in response to a temperature gradient,

$$α = \frac{Δ U}{∇ T}$$

and has units of VK⁻¹, though typical values are in the range of microvolts per Kelvin.

A thermoelectric device typically includes two types of semiconducting material (e.g., n-type and p-type) though thermoelectric devices comprising a single thermoelectric material (either n-type or p-type) are also known. Conventionally, both n-type and p-type conductors are used to form n-type and p-type legs within a device. Because the equilibrium concentration of carriers in a semiconductor is a function of temperature, if a temperature gradient is placed across a device with n-type and p-type legs, the carrier concentrations in both legs will differ. The resulting motion of charge carriers will create an electric current.

For purely p-type materials that have only positive mobile charge carriers (holes), α>0. For purely n-type materials that have only negative mobile charge carriers (electrons), α<0. In practice, materials often have both positive and negative charge-carriers, and the sign of α usually depends on which of them predominates.

The maximum efficiency of a thermoelectric material depends on the amount of heat energy provided and on materials properties such as the Seebeck coefficient, electrical resistivity and thermal conductivity. A figure of merit, ZT, can be used to evaluate the quality of thermoelectric materials. ZT is a dimensionless quantity that for small temperature difference is defined by ZT=σα²T/κ, where σ is the electric conductivity, α is the Seebeck coefficient, T is temperature, and K is the thermal conductivity. Another indicator of thermoelectric material quality is the power factor, PF=σα².

A material with a large figure of merit will usually have a large Seebeck coefficient (found in low carrier concentration semiconductors or insulators) and a large electrical conductivity (found in high carrier concentration metals). Thermoelectric materials advantageously have high electrical conductivity, high Seebeck coefficient, and low thermal conductivity. These properties are difficult to optimize simultaneously, and an improvement in one often comes at the detriment of another. For instance, most insulators, which have low electron densities, have a low electrical conductivity but a high Seebeck coefficient.

Good thermoelectric materials are typically heavily-doped semiconductors or semimetals with a carrier concentration of 10¹⁹ to 10²¹ carriers/cm. Moreover, to ensure that the net Seebeck effect is large, there should only be a single type of carrier. Mixed n-type and p-type conduction will lead to opposing Seebeck effects and lower thermoelectric efficiency. In materials having a sufficiently large band gap, n-type and p-type carriers can be separated, and doping can be used to produce a dominant carrier type. Thus, good thermoelectric materials typically have band gaps large enough to have a large Seebeck coefficient, but small enough to have a sufficiently high electrical conductivity.

Further, a good thermoelectric material advantageously has a low thermal conductivity. Thermal conductivity in such materials comes from two sources. Phonons traveling through the crystal lattice transport heat and contribute to lattice thermal conductivity, and electrons (or holes) transport heat and contribute to electronic thermal conductivity.

One approach to enhancing ZT is to minimize the lattice thermal conductivity. This can be done by increasing phonon scattering, for example, by introducing heavy atoms, disorder, large unit cells, clusters, rattling atoms, grain boundaries and interfaces.

Previously-commercialized thermoelectric materials include bismuth telluride- and (Si,Ge)-based materials. The family of (Bi,Pb)₂(Te,Se,S)₃ materials, for example, has a figure of merit in the range of 1.0-1.2. Slightly higher values can be achieved by selective doping, and still higher values can be reached for quantum-confined structures. However, due to their chemical stability and melting point, the application of these materials is limited to relatively low temperatures (<450° C.), and even at such relatively low temperatures, they require protective surface coatings. Other known classes of thermoelectric materials such as clathrates, skutterudites and silicides also have limited applicability to elevated temperature operation.

In view of the foregoing, it would be advantageous to develop a thermoelectric device capable of efficient operation at elevated temperatures. More specifically, it would be advantageous to develop environmentally-friendly, high-temperature thermoelectric materials having a high figure of merit in the medium-to-high temperature range.

These and other aspects and advantages of the invention can be achieved by a multiphase thermoelectric material comprising a titania-based semiconducting phase and a half-metal conducting phase. The multiphase thermoelectric material is advantageously a nanocomposite material wherein the constituent phases are uniformly distributed and have crystallite sizes ranging from about 10 nm to 800 nm. Advantageously, the titania-based semiconducting phase is a sub-stoichiometric phase of titanium oxide that has been partially reduced by the half-metal conducting phase.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and together with the description serve to explain the principles and operations of the invention.

### BRIEF DESCRIPTION OF THE DRAWINGS

FIG. 1 shows a series of X-ray diffraction scans for multiphase thermoelectric materials according to one embodiment;

FIGS. 2A-2C are scanning electron micrographs for a 75:25 (wt. %) titanium oxide:titanium carbide multiphase thermoelectric material showing (A) powder material; (B) a fracture surface for dense composite material; and (C) a polished surface for dense composite material;

FIG. 3 is a plot of electrical conductivity versus temperature for several titanium oxide-titanium carbide multiphase thermoelectric materials;

FIG. 4 is a plot of Seebeck coefficient versus temperature for several titanium oxide-titanium carbide multiphase thermoelectric materials;

FIG. 5 is a plot of electrical conductivity versus temperature for several comparative single phase thermoelectric materials;

FIG. 6 is a plot of Seebeck coefficient versus temperature for several comparative single phase thermoelectric materials;

FIG. 7 is a plot of electrical conductivity versus temperature for several titanium oxide-titanium nitride multiphase thermoelectric materials;

FIG. 8 is a plot of Seebeck coefficient versus temperature for several titanium oxide-titanium nitride multiphase thermoelectric materials;

FIG. 9 is a plot of thermal conductivity versus temperature for several titanium oxide-titanium nitride multiphase thermoelectric materials; and

FIG. 10 is a plot of electrical conductivity versus temperature for several titanium oxide-titanium carbide multiphase thermoelectric materials showing the effects of an optional annealing step.

FIG. 11 is a plot of Seebeck coefficient versus temperature for several titanium oxide-titanium carbide multiphase thermoelectric materials showing the effects of an optional annealing step.

### DETAILED DESCRIPTION

As used herein, the singular forms “a,” “an” and “the” include plural referents unless the context clearly dictates otherwise. Thus, for example, reference to “an oxide” includes examples having two or more such “oxides” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

The invention relates generally to high temperature thermoelectric materials and methods of making such materials. The inventive materials are composites comprising both a titania-based semiconducting phase and a half-metal conducting phase. Advantageously, the composite is a nanoscale composite where the constituent phases have grain or particle sizes of less than one micrometer. According to embodiments, the titania-based semiconducting phase and the half-metal conducting phase are homogeneously distributed throughout the material and each have an average crystallite size of between about 10 nm and 800 nm.

The titania-based semiconducting phase is advantageously titanium oxide, and the half-metal conducting phase can be a metal carbide, metal nitride or metal boride (e.g., TiC, TiN, SiC, etc.). Advantageously, the titania-based semiconducting phase is at least partially reduced by the half-metal conducting phase, which in the example of titanium oxide results in the formation of sub-stoichiometric titanium oxide. In such embodiments, the inventive composite is a multiphase material comprising titanium oxide and/or its sub-stoichiometric phases and at least one of a metal carbide, nitride or boride. Titanium oxide (TiO₂) and its various sub-stoichiometric forms (TiO₂—X) are also referred to as titania.

The composite thermoelectric material may further include additional phases and can include, for example, partial substitution of titanium in the titania-based semiconducting phase by other elements (dopants) such as Li, Na, V, Nb, Ta, Cr, Mo, W, C, N and/or S. By way of example, metallic dopants (Li, Na, V, Nb, Ta, Cr, Mo, W) can be substituted for Ti on cationic sites and/or incorporated on interstitial sites. If included, carbon, nitrogen and/or sulfur can be incorporated on anionic sites.

By way of background, select properties of example constituent phases in the inventive multiphase high temperature thermoelectric materials are discussed below.

Undoped titanium oxide is an n-type semiconductor with a bandgap of about 3 eV. The intrinsic n-type character is caused by donor-type defects such as oxygen vacancies and interstitial titanium cations. Titanium vacancies, on the other hand, produce p-type conduction but are only present in considerable concentrations at high oxygen activity and, furthermore, are largely immobile and require very high temperatures for equilibration.

Based on titanium oxide's defect chemistry, the electrical conductivity can be enhanced in the low oxygen activity regime where titanium interstitials are the dominant defects and where their concentration increases with decreasing oxygen activity. Stoichiometric rutile, for example, exhibits a large themopower, but has extremely low electrical conductivity in air. At low oxygen activity, the intrinsic point defect chemistry promotes formation of Ti³⁺ in the rutile structure so that the partially-reduced material develops improved electronic conductivity.

The effect of dopants on the defect chemistry, electrical conductivity and Seebeck coefficient of titanium oxide has been considered mainly for n-type dopants such as niobium and tantalum. Niobium-doping, for example, can create a high concentration of electrons and increases the electronic conductivity by several orders of magnitude. Further, by doping with niobium, metallic-like conduction can be obtained at low oxygen activity while semiconductor behavior prevails at high oxygen activity.

Sub-stoichiometric (e.g., partially-reduced) titanium oxide includes Magnéli phases (TiO₂₋ₓ), which are oxide materials based on Ti³⁺ and Ti⁴⁺, as well as more heavily-reduced titanium oxides (e.g., TiO_{1.1-1.2}), which are based on Ti²⁺.

Titanium carbide and titanium nitride are example half-metal conducting phases. Each crystallizes in the rock salt structure and exhibits a wide range of stoichiometry. The composition of titanium carbide, for example, can vary as expressed by the chemical formula, TiCₓ (0.6<x<1). Although both materials are relative poor thermoelectrics, each has a high electrical conductivity and can contribute to the electrical conductivity in composites comprising either phase. Due to their metallic nature, and by way of example, the thermal conductivity of titanium carbide at room temperature is on the order of about 20 W/mK, and the thermal conductivity of titanium nitride at 800° C. is about 42 W/mK.

It has been determined experimentally that the partial oxidation of titanium nitride can produce TiN-containing composite materials. Our research in this area aided in the conception of the multiphase thermoelectric material concept according to the present invention. Partially-oxidized titanium nitride composite materials may include, for example, a core of substantially un-oxidized titanium nitride grains surrounded by a shell of titanium oxide. The oxide shell can include stoichiometric titanium oxide as well as one or more sub-stoichiometric phases of titanium oxide with compositions ranging between TiO₂ and Ti₂O₃. The sub-stoichiometric phases of titanium oxide can be Magnéli phases that comprise an extremely high density of line defects. In addition, they may include a high density of nanoporosity. This partial oxidation of a dense TiN ceramic can be performed by heating the nitride at 1000° C. in the presence of oxygen for about 1 hour.

In inventive titanium oxide-titanium carbide and titanium oxide-titanium nitride composites, the intrinsic oxygen activity is low due to the co-existence of the oxide with the carbide or nitride. As a result, these composite materials have an electrical conductivity higher than that of the oxide alone. In embodiments, the overall electrical conductivity of the composite is high due to contributions from both sub-stoichiometric titanium oxide and the half-metal phase. Specifically, exposure of titanium oxide to TiC or TiN leads to doping of the oxide with carbon or nitrogen. Both dopants promote n-type conductivity and create respectively discontinuous (in the case of carbon) or continuous (in the case of nitrogen) intergap states, which reduce the bandgap and enhance electronic conductivity. In addition, due to chemical reactions that occur during processing, nanopores can form at the titanium oxide-half metal interface, which further decrease the thermal conductivity.

In layered or block sub-stoichiometric titanium oxide structures or titanium oxide nanocrystalline material, quantum confinement can lead to an increased contribution of the Seebeck coefficient. However, a theoretical evaluation of the Seebeck coefficient for the inventive multiphase composites is more difficult than the circuit evaluation used for the electrical conductivity in single phase materials due to the presence of interfaces and a space charge layer at the interface.

In a first approximation, the interface in the inventive multiphase thermoelectric materials can be considered a semiconductor-metal boundary with TiO₂ being the semiconductor component and the half-metal phase being the metallic component. In that configuration, the half-metal phase imposes the formation of a space charge layer in the oxide with an imposed high electron concentration at the interface. In embodiments comprising nanoscale phases, the small particle size and high interfacial density can promote phonon scattering, which results in a thermal conductivity that is substantially lower than that of the constituent phases.

Due in part to their high figure of merit, high thermal shock resistance, thermal and chemical stability and relatively low cost, the multiphase thermoelectric materials according to the present invention can be used effectively and efficiently in a variety of applications, including automotive exhaust heat recovery. Though heat recovery in automotive applications involves temperatures in the range of about 400-750° C., the multiphase thermoelectric materials can withstand chemical decomposition in non-oxidizing environments or, with a protective coating, in oxidizing environments up to temperatures as high as about 1000° C.

A method of making a multiphase thermoelectric material comprises forming a composite powder having a core of a first phase and an outer shell of a second phase by heating a powder of the first phase under conditions effective to form a second phase on an outer-surface portion thereof, and densifying the composite powder to form a multiphase thermoelectric material, wherein the first material and the second material are different and are selected from the group consisting of a titania-based semiconducting material and a half-metal conducting material.

A further method of making a multiphase thermoelectric material comprises combining a powder of a titania-based material and a powder of a half-metal material to form a powder mixture, and densifying the powder mixture to form a multiphase thermoelectric material. According to embodiments, nanoscale powders of the constituent materials are initially dispersed in a liquid and mixed ultrasonically, dried and sieved. The liquid is used to promote dispersion and homogenous mixing of the powders and can advantageously include an alcohol such as ethanol or isopropanol.

In a further embodiment, the titania-based powders can be derived from Ti-precursors such as titanium alcoholates (e.g., titanium isopropoxide), titanium chlorides, or other organic or inorganic compounds. One or more precursors, including dopants precursors, can be mixed in organic solvents and then decomposed via the addition of water or other decomposition agent to form a gel, hydrogel or oxide. The decomposition product can be dehydrated and densified.

According to embodiments, the titania-based powder has a crystallite size of 10-50 nm, and the powder of the half-metal conducting phase has a crystallite size of 100-400 nm. For example, rutile and TiC powders having crystallite sizes of around 30 nm and 200 nm, respectively, can be used. The powder mixture can comprise any suitable ratio of the constituent materials, and can include ratios of the titania-based semiconducting phase to the half-metal conducting phase ranging from about 2:98 to 98:2. Example ratios of the titania-based semiconducting phase to the half-metal conducting phase include 2:98, 5:95, 10:90, 15:85, 20:80, 25:75, 30:70, 35:65, 40:60, 45:55, 50:50, 55:45, 60:40, 65:35, 70:30, 75:25, 80:20, 85:15, 90:10, 95:5 and 98:2.

In an exemplary method, a powder mixture can be placed into a graphite die, which is loaded into a Spark Plasma Sintering (SPS) apparatus where the powder mixture is heated and densified under vacuum and under applied pressure using a rapid heating cycle. Spark Plasma Sintering is also referred to as Field Assisted Sintering Technique (FAST) or Pulsed Electric Current Sintering (PECS). Of course, other types of apparatus can be used to mix and compact the powder mixture. For example, powders can be mixed using ball milling or spraying, and a hot isostatic press operated at high heating rates can be used to compact the mixture.

Heating cycles with hold (maximum) temperatures of about 900-1400° C. can be used in conjunction with heating rates from about 450° C. to the hold temperature of greater than 100° C./min (e.g., between about 100 and 400° C./minute), and hold times of from about 30 seconds to 10 minutes. A pressure of between about 3 to 60 MPa can be applied to the powder mixture to affect densification.

Samples are advantageously cooled rapidly from the hold temperature to room temperature. Typical samples are disk-shaped, have a thickness in the range of about 2-3 mm and a diameter of about 20 mm. Optionally, after densification, samples can be annealed at different temperatures in either a reducing or oxidizing atmosphere. An annealing temperature can range from about 600° C. to 1100° C., and an annealing time can range from about 12 to 60 hours.

Table 1 summarizes the compositions and process conditions used to prepare multiphase thermoelectric materials according to the invention. For comparison, Table 1 also includes process data for “single phase” titanium oxide and titanium carbide samples. The comparative samples are identified with a dagger (t) and have a powder mixture composition where one of the phases is zero. For example, a 0:1 ratio of TiO₂:TiC means a pure TiC comparative sample, i.e., where TiO₂ powder is omitted from the mixture, and a 1:0 ratio of TiO₂:TiC means a pure TiO₂ comparative sample, i.e., where TiC powder is omitted from the mixture.

In Table 1, for each sample, the experimental run number is also listed. The ratio of precursor powders based on weight is given by TiO₂:TiC, TiO₂:TiN, or TiO₂:SiC. Tₘₐₓ is the hold (maximum) temperature, and Rate represents the heating rate from 450° C. to the hold temperature. In Table 1, Time represents the hold time for each respective sample at the hold temperature. For each sample a uniaxial pressure of 30 MPa was applied during the heating cycle. With the exception of Sample #4, which was heated in flowing nitrogen, all samples were heated and densified in an SPS apparatus under vacuum.

An optional post-anneal was conducted at the temperature and for the time indicated. With the exception of Sample 13, which was annealed in air (i.e., under oxidizing conditions), all samples that were annealed were annealed in a graphite crucible (i.e., under reducing conditions).

TABLE 1
Process condition summary for multiphase thermoelectric materials

| Sample # | Run # | | Tmax [° C.] | Rate [° C./min] | Time [min] | Post-anneal [° C.], [hr] |
|---|---|---|---|---|---|---|
| | | TiO₂:TiC | | | | |
| 1^{†} | 89 | 0:1 | 1100 | 200 | 2 | No |
| 2 | 156 | 1:3 | 1100 | 200 | 2 | No |
| 3 | 2 | 1:1 | 1000 | 200 | 2 | No |
| 4 | 15 | 1:1 | 1000 | 100 | 2 | No |
| 5 | 115A | 1:1 | 1100 | 200 | 2 | No |
| 6 | 115B | 1:1 | 1100 | 200 | 2 | 1000, 20 |
| 7 | 102 | 1:1 | 1100 | 400 | 1 | No |
| 9 | 23 | 2:1 | 1100 | 200 | 2 | No |
| 10 | 24 | 2:1 | 1100 | 200 | 2 | No |
| 11 | 97A | 2:1 | 1100 | 200 | 2 | 700, 20 |
| 12 | 97B | 2:1 | 1100 | 200 | 2 | 1000, 20 |
| 13 | 97C | 2:1 | 1100 | 200 | 2 | 700, 50 |
| 14 | 100A | 2:1 | 1100 | 400 | 1 | No |
| 15 | 100B | 2:1 | 1100 | 400 | 1 | 1000, 20 |
| 16 | 4 | 5:1 | 1000 | 100 | 5 | No |
| 17 | 19 | 5:1 | 1000 | 200 | 2 | No |
| 18 | 26A | 5:1 | 1100 | 150 | 2 | No |
| 19 | 26B | 5:1 | 1100 | 150 | 2 | 1000, 20 |
| 20 | 27A | 5:1 | 1300 | 200 | 2 | No |
| 21 | 27B | 5:1 | 1300 | 200 | 2 | 700, 20 |
| 22 | 27C | 5:1 | 1300 | 200 | 2 | 1000, 20 |
| 23 | 103 | 5:1 | 1100 | 400 | 1 | No |
| 24 | 154 | 10:1 | 1100 | 200 | 2 | No |
| 25 | 155 | 10:1 | 1100 | 200 | 2 | 1000, 20 |
| 26^{†} | 1A | 1:0 | 800 | 200 | 2 | No |
| 27^{†} | 1B | 1:0 | 800 | 200 | 2 | 700, 20 |
| 28^{†} | 1C | 1:0 | 800 | 200 | 2 | 1000, 20 |
| 29^{†} | 3 | 1:0 | 900 | 350 | 2 | No |
| | | TiO₂:TiN | | | | |
| 33 | 169 | 1:1 | 1100 | 200 | 2 | No |
| 34 | 170 | 2:1 | 1100 | 200 | 2 | No |
| 35 | 171 | 3:1 | 1100 | 200 | 2 | No |
| | | TiO₂:SiC | | | | |
| 36 | 91 | 5:1 | 1000 | 300 | 2 | No |
| 37 | 121 | 5:1 | 1100 | 200 | 2 | No |
| 38 | 9A | 10:1 | 1100 | 200 | 3 | No |
| 39 | 9B | 10:1 | 1100 | 200 | 3 | 700, 20 |
| 40 | 118 | 10:1 | 1100 | 200 | 2 | No |
| 41 | 120 | 10:1 | 1000 | 230 | 2 | No |
| 42 | 116 | 20:1 | 1100 | 200 | 2 | No |

^{†}comparative

A variety of characterization tools were used to evaluate the as-densified and post-annealed multiphase thermoelectric composite materials. Microstructural characterization was obtained using X-ray diffraction (XRD) and scanning electron microscopy (SEM).

According to the XRD results, the amount of sub-stoichiometric titanium oxide in the composites was influenced by the initial composition, as well as by the densification and annealing conditions. Pure titanium oxide samples (comparative) produced under all densification conditions exhibited rutile and in some cases minor contributions of anatase, but did not show significant contributions of sub-stoichiometric titanium oxide. In a similar vein, TiC samples (comparative) revealed only TiC in their spectrum.

For compositions derived from titanium oxide and titanium carbide starting materials, the XRD scans showed rutile, significant levels of sub-stoichiometric titanium oxide and titanium carbide. Annealing in a closed graphite chamber at 700° C. for 20 h did not significantly modify the titanium oxide stoichiometry. However, annealing in a closed graphite chamber at 1000° C. for 20 h produced some sub-stoichiometric titanium oxide in the case of pure titania (e.g., example 28) or increased the amount present (e.g., sample 6).

After processing, in all composites the sub-stoichiometric titanium oxide peaks were very numerous and broad, indicating contribution from several Magnéli phases and/or a small grain size or block structure. Titanium oxide-titanium carbide composites annealed in air displayed XRD scans consistent with oxidized titanium carbide, the formation of sub-stoichiometric titanium oxide and the formation of a surface layer of rutile. The rutile layer was not found to be protective up to thickness of at least 1 mm.

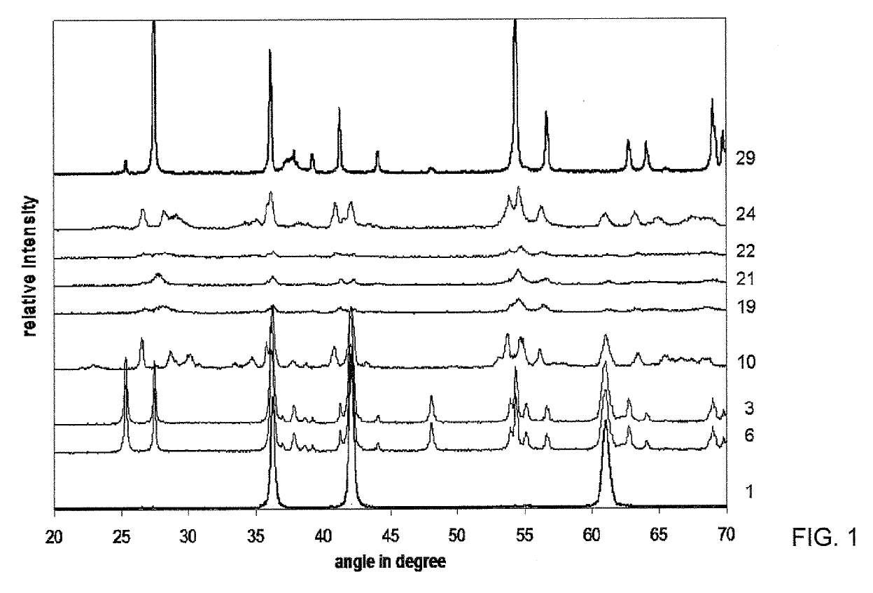

A series of XRD scans are shown in FIG. 1 for select samples. In FIG. 1, curves 1 and 29, which correspond respectively to TiC and TiO₂, are shown for comparison. Each curve is identified by sample number (as defined in Table 1). Composites with a high TiO₂:TiC ratio exhibited high levels of Ti₄O₇ and Ti₅O₈, while composites with a low TiO₂:TiC ratio exhibited a mixture of sub-stoichiometric oxides, including Ti₄O₇, Ti₅O₉, Ti₅O₉, Ti₆O₁₁, Ti₇O₁₃, Ti₈O₁₅, and others.

Polished cross-sections of titanium oxide-titanium carbide composite materials were analyzed using high resolution SEM. In the phase contrast mode, titanium oxide and titanium carbide were in direct contact. No additional phases were observed. Rutile and sub-stoichiometric titanium oxide were not distinguished.

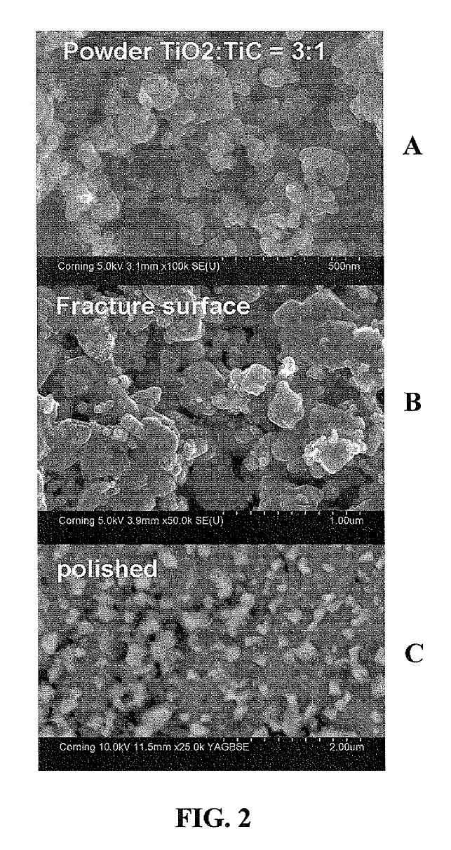

Scanning electron micrographs for a 75:25 (wt. %) titanium oxide:titanium carbide multiphase thermoelectric material are shown in FIG. 2. FIG. 2A shows a powder specimen, FIG. 2B shows a fracture surface for a corresponding densified composite material, and FIG. 2C shows a polished cross section of the densified composite material.

Thermoelectric properties were obtained from as-densified and annealed samples that were cut into coupons measuring 2-3 mm×2-3 mm×12-14 mm. Both the Seebeck coefficient and the electrical conductivity were measured simultaneously using a ULVAC-ZEM3 device from room temperature up to 800° C. The thermal conductivity was obtained at 26° C., 300° C., 750° C. and 1000° C. from the product of the geometrical density, the heat capacity and the thermal diffusivity, which were determined using a thermal property analyzer (Anter Corp., Pittsburgh, Pa.). Thermoelectric properties are summarized in Tables 2 and 3. Where no measurement was made, no data is presented.

TABLE 2
Thermoelectric properties of multiphase thermoelectric materials

| | | Seebeck | Seebeck | | | Thermal | Thermal |
|---|---|---|---|---|---|---|---|
| | | Coefficient | Coefficient | Electrical | Electrical | conductivity | Conductivity |
| | | @750 K | @1000 K | Conductivity | Conductivity | @750 K | @1000 K |
| | Sample # | [μV/K] | [μV/K] | @750 K [S/m] | @1000 K [S/m] | [W/mk] | [W/mk] |
| 1^{†} | 89 | −36.96 | −65.08 | 31496 | 10021 | | |
| 2 | 156 | −38.8 | −45.9 | 41654 | 45947 | 2.57 | 3.13 |
| 4 | 15 | | | | | 1.28 | 1.34 |
| 5 | 115A | −65.87 | −75.11 | 31969 | 23361 | | |
| 6 | 115B | −74.09 | −84.00 | 17686 | 12810 | | |
| 7 | 102 | −66.73 | −80.15 | 33671 | 25508 | 3.12 | 3.45 |
| 9 | 23 | −162.57 | −177.07 | 13968 | 13596 | | |
| 10 | 24 | −159.07 | −170.72 | 16968 | 15713 | | |
| 11 | 97A | −160.63 | −170.92 | 12447 | 12277 | | |
| 12 | 97B | −153.21 | −167.03 | 17921 | 17500 | | |
| 13 | 97C | −159.04 | −182.48 | 4705 | 4902 | | |
| 14 | 100A | −85.09 | −104.37 | 30796 | 23024 | 2.23 | 2.26 |
| 15 | 100B | −78.55 | −89.6 | 29300 | 25600 | 2.06 | 1.78 |
| 16 | 4 | −408.49 | −349.92 | 53 | 106 | 1.59 | 1.71 |
| 17 | 19 | −321.47 | −368.31 | 420 | 327 | | |
| 18 | 26A | −102.72 | −136.57 | 25868 | 35366 | | |
| 19 | 26B | −108.15 | −119.02 | 23140 | 17859 | | |
| 20 | 27A | −76.01 | −95.79 | 51681 | 46290 | | |
| 21 | 27B | −81.4 | −97.7 | 41167 | 37142 | | |
| 22 | 27C | −78.17 | −96.7 | 52895 | 48535 | | |
| 23 | 103 | −127 | −142 | 19800 | 15500 | 2.57 | 2.74 |
| 24 | 154 | −128.33 | −146.03 | 29799 | 27176 | 2.22 | 1.91 |
| 25 | 155 | −125 | −136 | 29740 | 27600 | 2.58 | 2.31 |
| 26^{†} | 1A | −643 | −642 | 29 | 34 | 2.1 | 2.2 |
| 27^{†} | 1B | −640 | −610 | 30 | 33 | 2 | 2.1 |
| 28^{†} | 1C | −450.82 | −467.78 | 473 | 513 | 1.8 | 1.9 |
| 29^{†} | 3 | −645.97 | −645.18 | 28.50 | 35.02 | | |
| 33 | 169 | −62.3 | −72.1 | 97100 | 53100 | 6.6 | 6.1 |
| 34 | 170 | −117 | −130 | 37200 | 31200 | 3.6 | 3 |
| 35 | 171 | −136 | −145 | 31700 | 29600 | 3.2 | 2.7 |
| 36 | 91 | −388.55 | −448.63 | 283.64 | 29.09 | 1.36 | 1.32 |
| 37 | 121 | −236 | −440 | 2758 | 1770 | | |
| 38 | 9A | −281.10 | −313.21 | 1507.96 | 508.71 | | |
| 39 | 9B | −359.51 | −448.63 | 563.98 | 203.83 | | |
| 40 | 118 | −285 | −276 | 1893 | 1892 | 1.97 | 1.85 |
| 41 | 120 | −329 | −360 | 995 | 724 | | |
| 42 | 116 | −224 | −246 | 4397 | 4598 | 2.37 | 2.28 |

^{†}comparative

The electrical conductivity and Seebeck coefficient typically show inverse responses to parameter changes. For example, an increase in the maximum SPS heating temperature increases the electrical conductivity but decreases the Seebeck coefficient. This response is most likely due to grain growth at higher temperatures. Faster heating rates and shorter dwell times also promote an increase in Seebeck coefficient at lower electrical conductivity, reflecting an impact of unstructured (amorphous) grain boundary regions that decrease the electrical conductivity in such disorganized areas.

In embodiments, the multiphase thermoelectric material has an electrical conductivity greater than 10³ S/m, a Seebeck coefficient (absolute value) greater than 100 μV/K, and a thermal conductivity K over a temperature range of 400-1200K of less than 4 W/mK. By way of example, the electrical conductivity can be greater than 10³, 2×10³, 3×10³, 4×10³, 5×10³, 6×10³, 7×10³, 8×10³, 9×10³, 10⁴, 2×10⁴, 3×10⁴, 4×10⁴, 5×10⁴, 6×10⁴, 7×10⁴, 8×10⁴, 9×10⁴ or 10⁵ S/m, the absolute value of the Seebeck coefficient can be greater than 100, 150, 200, 250, 300 or 350 μV/K, and the thermal conductivity over the range of 400-1200K can be less than 4, 3.5, 3, 2.5, 2 or 1.5 W/mK. Further, the electrical conductivity, Seebeck coefficient and thermal conductivity may have values that extend over a range where the minimum and maximum values of the range are given by the values above. For example, a multiphase thermoelectric material that has an electrical conductivity greater than 103 S/m can also be defined as having an electrical conductivity between 2×10⁴ and 10⁵ S/m.

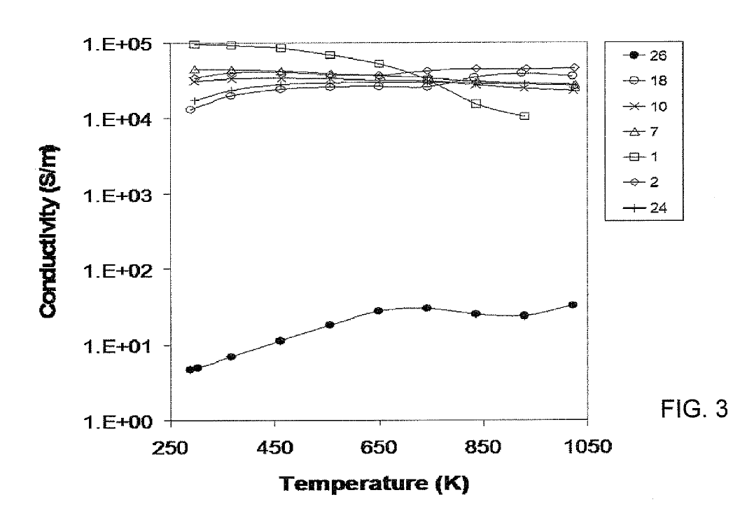

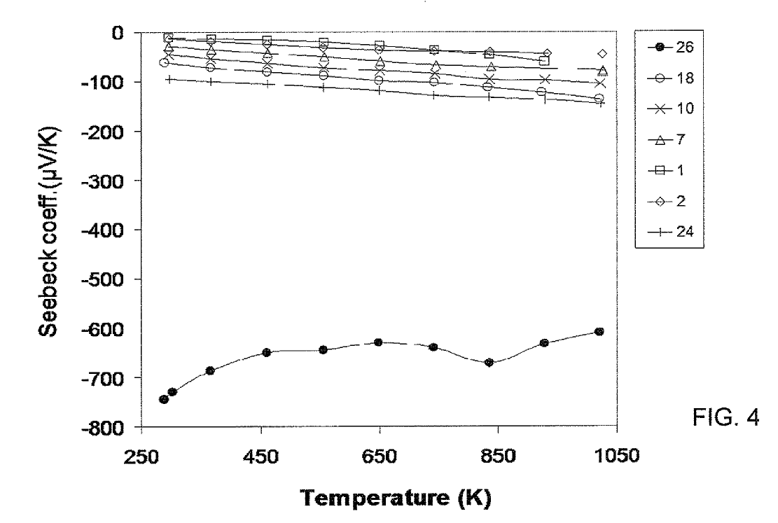

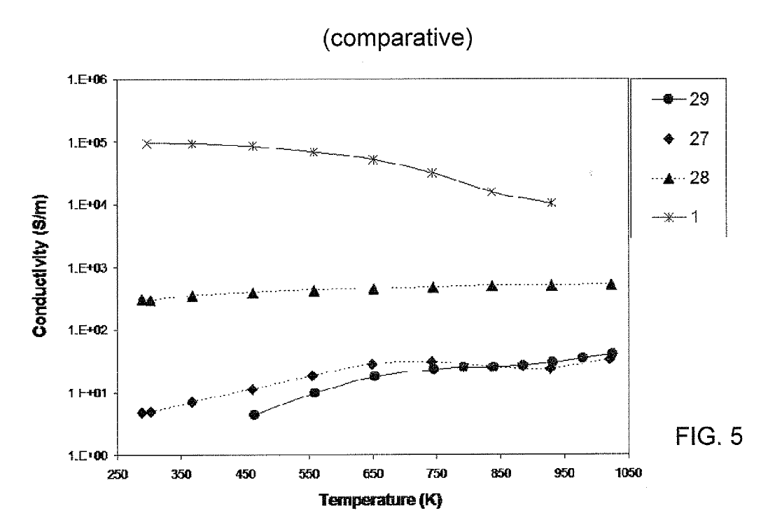

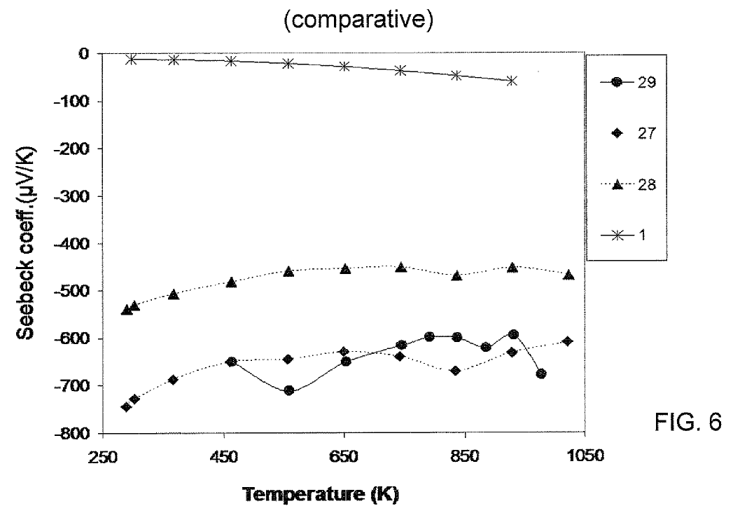

The effect of composition in titanium oxide-titanium carbide multiphase composite materials is shown in FIGS. 3 and 4. FIG. 3 is a plot of electrical conductivity versus temperature, and FIG. 4 is a plot of Seebeck coefficient versus temperature for various multiphase composite materials. Comparative electrical conductivity and Seebeck coefficient data are shown in FIGS. 5 and 6, which show results for “single phase” titanium oxide and titanium carbide samples.

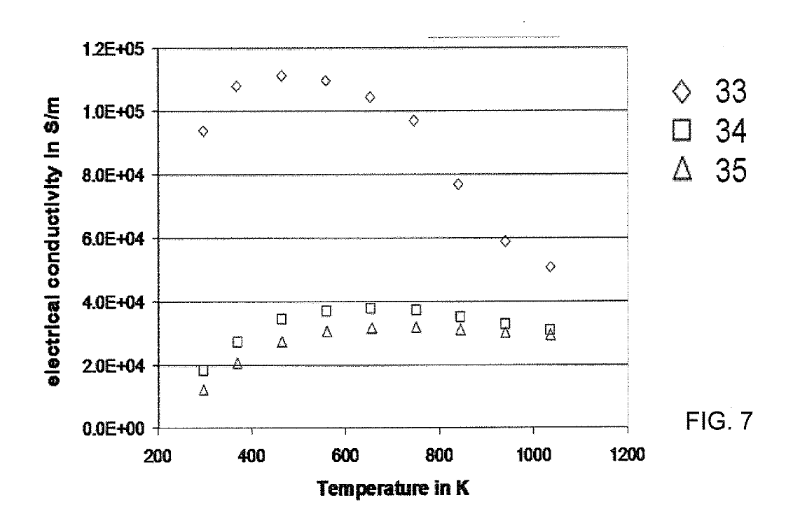

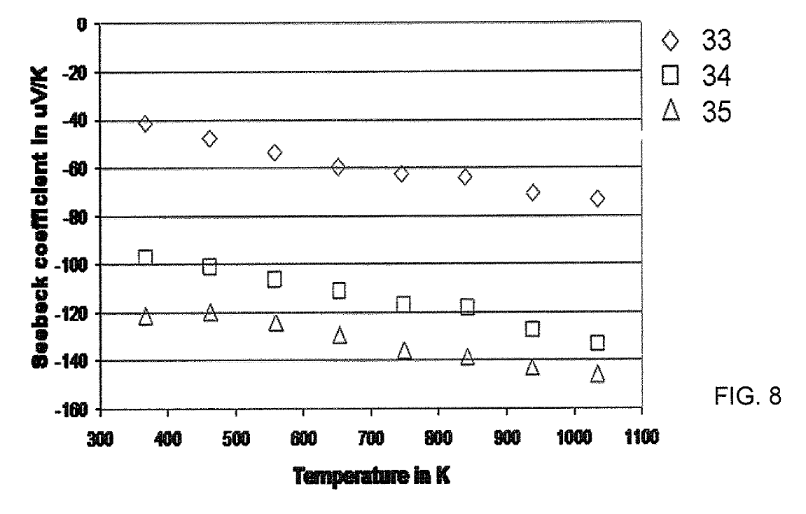

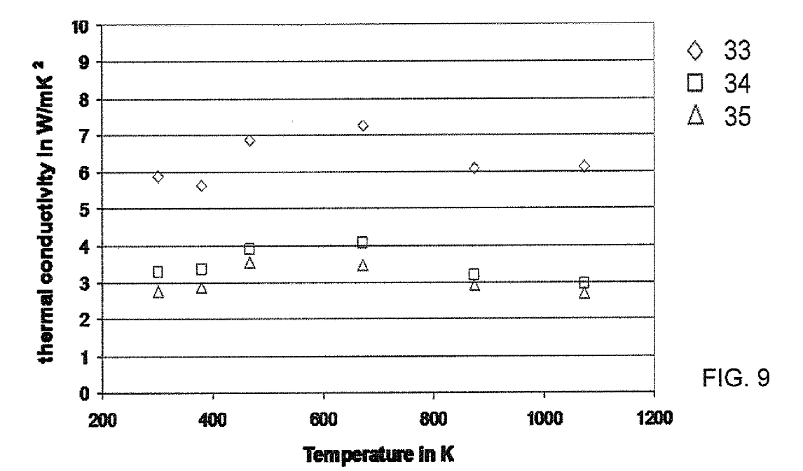

The effect of composition in titanium oxide-titanium nitride multiphase composite materials is shown in FIGS. 7-9. FIG. 7 is a plot of electrical conductivity versus temperature, FIG. 8 is a plot of Seebeck coefficient versus temperature, and FIG. 9 is a plot of thermal conductivity versus temperature for 1:1, 2:1, and 3:1 TiO₂:TiN multiphase composite materials.

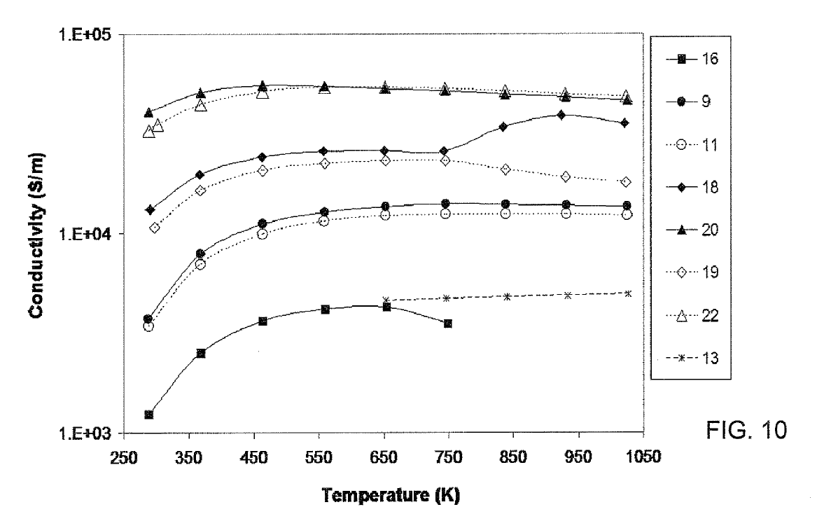

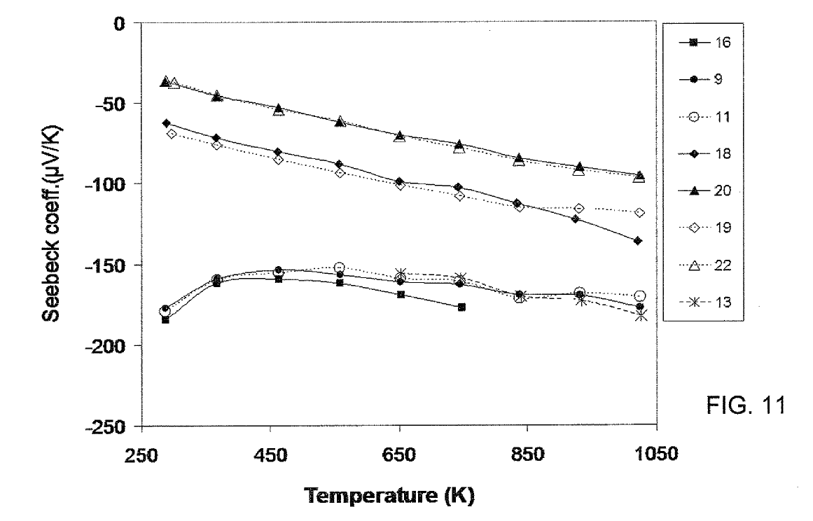

The effect of annealing on the electrical conductivity and Seebeck coefficient of titanium oxide-titanium carbide multiphase composite materials is shown in FIGS. 10 and 11. As with FIG. 1, the data in FIGS. 3-11 can be identified by the sample number in each respective key and with reference to Table 1.

Recalling that the power factor is defined as PF=σα², and the figure of merit is defined as ZT=σα²T/κ, according to embodiments the multiphase thermoelectric material has a power factor times temperature at 1000 K greater than about 0.1 W/mK (e.g., greater than 0.1, 0.15, 0.2, 0.25, 0.3, 0.35, 0.4, 0.45, 0.5, 0.55, 0.6 or 0.65 W/mK) and a figure of merit at 1000K greater than about 0.05 (e.g., greater than 0.05, 0.1, 0.15, 0.2, 0.25, or 0.3). Further, values of power factor times temperature and figure of merit may extend over a range where the minimum and maximum values of the range are given by the values above. Select power factor and figure of merit data for multiphase thermoelectric materials are summarized in Table 3.

TABLE 3
Power factor and figure of merit for multiphase thermoelectric materials

| | | Power factor * T | Power factor * T | | |
|---|---|---|---|---|---|
| Sample # | Run # | @750 K [W/mK] | @1000 K [W/mK] | ZT @ 750 K | ZT @ 1000 K |
| 1^{†} | 89 | 0.03 | 0.04 | | |
| 2 | 156 | 0.05 | 0.10 | 0.02 | 0.03 |
| 4 | 15 | | | | |
| 5 | 115A | 0.10 | 0.13 | | |
| 6 | 115B | | 0.09 | | |
| 7 | 102 | 0.11 | 0.16 | 0.04 | 0.05 |
| 9 | 23 | 0.28 | 0.43 | | |
| 10 | 24 | 0.32 | 0.46 | | |
| 11 | 97A | 0.24 | 0.36 | | |
| 12 | 97B | 0.32 | 0.49 | | |
| 13 | 97C | 0.09 | 0.16 | | |
| 14 | 100A | 0.17 | 0.25 | 0.07 | 0.11 |
| 15 | 100B | 0.14 | 0.21 | 0.07 | 0.12 |
| 16 | 4 | 0.01 | 0.01 | 0.00 | 0.01 |
| 17 | 19 | 0.03 | 0.04 | | |
| 18 | 26A | 0.20 | 0.66 | | |
| 19 | 26B | 0.20 | 0.52 | | |
| 20 | 27A | 0.22 | 0.42 | | |
| 21 | 27B | 0.20 | 0.35 | | |
| 22 | 27C | 0.24 | 0.45 | 0.09 | 0.17 |
| 23 | 103 | 0.24 | 0.31 | 0.11 | 0.16 |
| 24 | 154 | 0.37 | 0.58 | 0.14 | 0.25 |
| 25 | 155 | 0.35 | 0.51 | | |
| 26^{†} | 1A | 0.01 | 0.01 | 0.00 | 0.01 |
| 27^{†} | 1B | 0.01 | 0.01 | 0.00 | 0.01 |
| 28^{†} | 1C | 0.07 | 0.11 | 0.04 | 0.06 |
| 29^{†} | 3 | 0.07 | 0.15 | | |
| 33 | 169 | 0.28 | 0.28 | 0.04 | 0.05 |
| 34 | 170 | 0.38 | 0.53 | 0.11 | 0.18 |
| 35 | 171 | 0.44 | 0.62 | 0.14 | 0.23 |
| 36 | 91 | 0.03 | 0.01 | 0.02 | 0.00 |
| 37 | 121 | 0.12 | 0.34 | | |
| 38 | 9A | 0.09 | 0.05 | | |
| 39 | 9B | 0.05 | 0.04 | | |
| 40 | 118 | 0.12 | 0.14 | 0.06 | 0.08 |
| 41 | 120 | 0.08 | 0.09 | | |
| 42 | 116 | 0.17 | 0.28 | 0.07 | 0.12 |

^{†}comparative

### EXAMPLES

Methods of forming the inventive multiphase thermoelectric materials will be further illustrated by the following examples.

### Example 1

A mixture of nanoscale titanium oxide powder and nanoscale TiC powder is cold-pressed and then rapidly densified using spark plasma sintering.

### Example 2

A TiN—TiO₂₋ₓ ceramic material is prepared from partially oxidized TiN powder, oxidized at an intermediate partial pressure of oxygen to provide a TiN core-Ti-oxide shell structure for each grain, and then densified by cold-pressing followed by plasma spark sintering.

### Example 3

TiO₂ powder is partially-reduced and reacted at its periphery by exposure to carbon-containing reactants (carbon, CO, CO₂, hydrocarbons, organics) to form a TiC shell. The resulting material is pressed and densified.

### Example 4

TiC is densified with titanium metal powder in a partially-oxidizing environment.

### Example 5

TiC is substituted by TiN or SiC in any of the foregoing examples to form a titanium oxide/titanium nitride or titanium oxide/silicon carbide composite.

### Example 6

In any of the foregoing examples, Ti in the TiO₂ is partially or completely substituted by other elements (dopants) (e.g., vanadium) that also form Magnéli oxide phases.

It will be apparent to those skilled in the art that various modifications and variations can be made to the present invention without departing from the spirit and scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A multiphase thermoelectric material comprising:
a titania-based semiconducting phase; and
a half-metal conducting phase.

2. The thermoelectric material according to claim 1, wherein the titania-based semiconducting phase is at least partially reduced by the half-metal conducting phase.

3. The thermoelectric material according to claim 1, wherein the titania-based semiconducting phase and the half-metal conducting phase are uniformly distributed throughout the thermoelectric material.

4. The thermoelectric material according to claim 1, wherein the titania-based semiconducting phase and the half-metal conducting phase each have an average grain size of between about 10 nm and 800 nm.

5. The thermoelectric material according to claim 1, wherein a composition of the thermoelectric material, expressed as a ratio in weight percent of the titania-based semiconducting phase to the half-metal conducting phase, ranges from about 2:98 to 98:2.

6. The thermoelectric material according to claim 1, wherein the titania-based semiconducting phase is sub-stoichiometric titanium oxide.

7. The thermoelectric material according to claim 1, wherein the titania-based semiconducting phase further comprises one or more cationic dopants, one or more anionic dopants, or both.

8. The thermoelectric material according to claim 1, wherein the titania-based semiconducting phase further comprises a dopant selected from the group consisting of lithium, sodium, vanadium, niobium, tantalum, chromium, molybdenum, tungsten, carbon, nitrogen and sulfur.

9. The thermoelectric material according to claim 1, wherein the half-metal conducting phase is a carbide, nitride or boride.

10. The thermoelectric material according to claim 1, wherein the half-metal conducting phase is a carbide, nitride or boride of titanium or silicon.

11. The thermoelectric material according to claim 1, wherein the thermoelectric material comprises sub-stoichiometric titanium oxide and at least one of titanium carbide and titanium nitride.

12. The thermoelectric material according to claim 1, wherein the thermoelectric material has an electrical conductivity greater than 10³ S/m, a Seebeck coefficient (absolute value) greater than 100 μV/K, and a thermal conductivity over a temperature range of 400-1200K of less than 4 W/mK.

13. The thermoelectric material according to claim 1, wherein the thermoelectric material has a power factor times temperature, PF*T, greater than 0.1 W/mK at 1000K, the power factor, PF, being defined as
PF=σα²
where:
σ is electrical conductivity in units of [S/m];
α is Seebeck coefficient in units of [μV/K]; and
T is temperature in degrees Kelvin.

14. The thermoelectric material according to claim 1, wherein the thermoelectric material has a power factor times temperature, PF*T, greater than 0.4 W/mK at 1000K, the power factor, PF, being defined as
PF=σα²
where:
σ is electrical conductivity in units of [S/m];
α is Seebeck coefficient in units of [μV/K]; and
T is temperature in degrees Kelvin.

15. The thermoelectric material according to claim 1, wherein the thermoelectric material has a figure of merit greater than 0.05 at 1000K, the figure of merit, ZT, being defined as
$$ZT = \frac{{σα}^{2} T}{κ}$$
where:
σ is electrical conductivity in units of [S/m];
α is Seebeck coefficient in units of [μV/K];
κ is thermal conductivity in units of [W/mK]; and
T is temperature in degrees Kelvin.

16. The thermoelectric material according to claim 1, wherein the thermoelectric material has a figure of merit greater than 0.2 at 1000K, the figure of merit, ZT, being defined as
$$ZT = \frac{{σα}^{2} T}{κ}$$
where:
σ is electrical conductivity in units of [S/m];
α is Seebeck coefficient in units of [μV/K];
κ is thermal conductivity in units of [W/mK]; and
T is temperature in degrees Kelvin.

17. A method of making a multiphase thermoelectric material, said method comprising:
combining a powder of a titania-based material and a powder of a half-metal material to form a mixture; and
densifying the mixture to form a multiphase thermoelectric material.

18. The method according to claim 17, wherein the combining comprises:
forming a suspension of the powders in a liquid;
ultrasonicating the suspension to form a well-dispersed mixture of powder particles; and
drying and sieving the mixture.

19. The method according to claim 17, wherein the half-metal conducting material is a carbide, nitride or boride.

20. The method according to claim 17, wherein the half-metal conducting material comprises a carbide, nitride or boride.

21. The method according to claim 17, wherein the titania-based material is titanium metal powder and the densifying comprises heating the mixture in an atmosphere comprising oxygen.

22. The method according to claim 17, wherein the titania-based material is a titania-based semiconducting material and the densifying comprises heating the mixture in an atmosphere substantially free of oxygen.

23. The method according to claim 17, wherein the titania-based material is titanium oxide.

24. The method according to claim 17, wherein the powder of the titania-based material has a crystallite size of from 10-50 nm, and the powder of the half-metal conducting material has a crystallite size of from 100-400 nm.

25. The method according to claim 17, wherein the powder of the titania-based material and the powder of the half-metal conducting material are combined in a ratio, on a weight percent basis, of from about 2:98 to 98:2.

26. The method according to claim 17, wherein the densifying comprises heating the mixture in vacuum.

27. The method according to claim 17, wherein the densifying comprises simultaneously heating and applying pressure to the mixture.

28. The method according to claim 17, wherein the densifying comprises heating and applying pressure to the mixture within a graphite die.

29. The method according to claim 17, wherein the densifying comprises applying a pressure of from about 3-60 MPa to the mixture.

30. The method according to claim 17, wherein the densifying comprises heating the mixture at a heating rate greater than about 100° C./min to a densifying temperature of from about 900-1400° C. for a densifying time of from about 0.5-10 minutes.

31. The method according to claim 17, further comprising annealing the multiphase thermoelectric material in a reducing atmosphere at an annealing temperature of from 600° C. to 1100° C. for an anneal time of from about 12-60 hours.

32. A method of making a multiphase thermoelectric material, comprising:
forming a composite powder having a core of a first material and an outer shell of a second material by heating a powder of the first material under conditions effective to form a second material on an outer-surface portion thereof; and
identifying the composite powder to form a multiphase thermoelectric material, wherein the first material and the second material are different and are selected from the group consisting of a titania-based semiconducting material and a half-metal conducting material.

33. A thermoelectric device comprising the thermoelectric material according to claim 1.
